(19) United States
(12) Patent Application Publication
(10) Pub. No.: US 2016/0116648 A1
(43) Pub. Date: Apr. 28, 2016

(54) OPTICAL ELEMENT COMPRISING A MULTILAYER COATING, AND OPTICAL ARRANGEMENT COMPRISING SAME

(71) Applicant: Carl Zeiss SMT GmbH, Oberkochen (DE)

(72) Inventors: Robbert W. E. VAN DE KRUIJS, Nieuwegein (NL); Steven NYABERO, Utrecht (NL); Andrey E. YAKSHIN, Nieuwegein (NL); Frederik BIJKERK, Bosch en Duin (NL)

(21) Appl. No.: 14/927,054

(22) Filed: Oct. 29, 2015

Related U.S. Application Data
(63) Continuation of application No. PCT/EP2014/057637, filed on Apr. 15, 2014.

(30) Foreign Application Priority Data
Apr. 29, 2013 (DE) 102013207751.3

(51) Int. Cl. G02B 5/08; G03F 7/20; G02B 1/10

(52) U.S. Cl. CPC G02B 5/0891; G02B 1/10; G02B 5/085; G03F 7/7015

(57) ABSTRACT

An optical element (50), comprising: a substrate (52), and a multilayer coating (51) applied to the substrate (52), including: at least one first layer system (53) consisting of an arrangement of identically constructed stacks (X1 to X4) each having at least two layers (53a-d), and at least one second layer system (54) consisting of an arrangement of identically constructed stacks (Y1, Y2) each having at least two layers (54a, 54b), wherein, upon a thermal loading of the multilayer coating (51), the first layer system (53) is configured to experience an irreversible contraction of the thicknesses (d_{X}) of the stacks (X1 to X4) and the second layer system (54) is configured to experience an irreversible expansion of the thicknesses (d_{Y}) of the stacks (Y1, Y2).

### CROSS-REFERENCE TO RELATED APPLICATIONS

This is a Continuation of International Application PCT/EP2014/057637, which has an international filing date of Apr. 15, 2014, and the disclosure of which is incorporated in its entirety into the present Continuation by reference. The following disclosure is also based on and claims the benefit of and priority under 35 U.S.C. §119(a) to German Patent Application No. DE 10 2013 207 751.3, filed Apr. 29, 2013, which is also incorporated in its entirety into the present Continuation by reference.

### FIELD OF THE INVENTION

The invention relates to an optical element comprising a substrate, and comprising a multilayer coating applied to the substrate. The invention also relates to an optical arrangement, in particular a lithography apparatus, comprising at least one such optical element.

### BACKGROUND

Optical multilayer coatings can be used for example for increasing the reflectivity for radiation at a predefined wavelength (operating wavelength). Multilayer coatings for optical elements designed for the soft X-ray or EUV wavelength range (i.e. for wavelengths that are typically between 5 nm and 20 nm) generally have alternating layers composed of materials having high and low real parts of the complex refractive index. At an operating wavelength in the range around approximately 13.5 nm, the alternating layers are typically molybdenum and silicon, the layer thicknesses of which are coordinated with one another and with the operating wavelength for a given angle of incidence such that the coating can fulfil its optical function and, in particular, a high reflectivity is ensured.

When the multilayer coatings on such and other optical elements are heated to high temperatures of e.g. more than 60° to 100° C., and even to 300° C. or higher, thermally governed changes in the multilayer coatings can occur, however, which adversely affect the optical properties of the optical elements. In particular, the period length of layers applied by means of conventional coating methods can change irreversibly in the event of relatively long operation at high temperatures. In this case, the period length of the multilayer coating can increase or decrease depending on the mechanisms underlying the change, for example material densification after interdiffusion or mixing of the layer materials at the interfaces of the layers. As a consequence of this changed period length, the angle-dependent reflected wavelength, intensity and wavefront typically change, which reduces the optical performance of the coating.

In order to increase the thermal stability of coatings, it is known to provide diffusion barriers in the form of barrier layers between adjacent layers of a multilayer coating, in order to prevent the mixing of the layer materials. One disadvantage of the use of such barrier layers is that the reflectivity losses brought about by the barrier layers increase with the effective barrier thickness, such that the performance of the coating is significantly reduced for thick barrier layers.

WO 2007/090364 discloses that layers composed of molybdenum and silicon that are arranged adjacently in a multilayer coating tend at high temperatures toward formation of molybdenum silicide as a result of interdiffusion processes at their interface, which leads to a reduction of the reflectivity on account of an irreversible decrease in the layer thickness and thus the period length of the layer pairs, which brings about a shift in the reflectivity maximum (or the centroid wavelength) of the multilayer coating for the incident radiation toward a shorter wavelength. In order to overcome this problem, WO 2007/090364 proposes using a silicon boride instead of silicon and a molybdenum nitride instead of molybdenum.

In order to solve the interdiffusion problem, DE 100 11 547 C2 proposes applying a barrier layer composed of Mo₂C at the interface between a silicon layer and a molybdenum layer, in order to prevent the interdiffusion between the layers and thereby to improve the thermal stability of the multilayer coating.

DE 10 2004 002 764 A1 in the name of the present applicant discloses that the layers of a multilayer coating, during the application thereof using specific coating methods, have an amorphous structure with a lower density than the corresponding materials in the form of a solid. The initially low density of the layers increases irreversibly at elevated temperatures, thus resulting in a reduction of the layer thicknesses of the individual layers and, in association with this, a decrease in the period length of the coating. This likewise has the consequence that the wavelength at which the multilayer coating assumes a maximum of the reflectivity is shifted. In order to solve this problem, DE 10 2004 002 764 A1 proposes providing an oversize during the application of the layers, and anticipating the irreversible reduction of the layer thicknesses by heat treatment of the multilayer coating before the latter is used in an optical arrangement.

The article “Interlayer growth in Mo/B4C multilayered structures upon thermal annealing”, by S. L. Nyabero et al., J. Appl. Phys, 113, 144310 (2013), discloses that the period thickness of Mo/B₄C multilayer structures can expand or decrease upon thermal treatment in the form of annealing. For molybdenum layers having a layer thickness of 3 nm, two different phenomena were observed depending on the thickness of the B₄C layer: first, in the case of multilayer coatings having B₄C thicknesses <1.5 nm, the supply of molybdenum to an MoBₓC_{y} interlayer that had already formed was dominant and led to a densification which had the consequence of a compaction of the periods. Second, in the case of multilayer coatings having a B₄C thickness >2 nm, the enrichment of B and C in interlayers led to the formation of mixtures having a low density and to period expansion, wherein, with these layer thicknesses, too, a compaction of the layer periods was observed in the event of a relatively long thermal treatment at temperatures of approximately 350° C.

### SUMMARY

It is an object of the invention to provide an optical element comprising a multilayer coating, and an optical arrangement, in particular a lithography apparatus, comprising at least one such optical element in which the optical properties of the multilayer coating are not impaired, or are only slightly impaired, even upon high thermal loadings lasting for a relatively long period of time.

This object is achieved through an optical element, comprising: a substrate, and a multilayer coating applied to the substrate, wherein the multilayer coating comprises: at least one first layer system consisting of an arrangement of identically constructed stacks each having at least two layers, and at least one second layer system consisting of an arrangement of identically constructed stacks each having at least two layers, wherein, upon a thermal loading of the multilayer coating, the first layer system is configured to experience an irreversible contraction (dependent on the intensity and the time duration of the thermal loading) of the thickness of the stacks and the second layer system is configured to experience an irreversible expansion (dependent on the intensity and the time duration of the thermal loading) of the thickness of the stacks. A number of identically constructed stacks of the first and second layer systems can be repeated in particular a plurality of times (periodically) in the multilayer coating.

The multilayer coating proposed here is composed of two (or more) layer systems, the first of which contracts (irreversibly) upon a thermal loading, i.e. upon a heat input into the layers of the layer system, as a result of chemical or physical conversion processes that take place in particular at the interfaces between the layers of the layer system, while an opposite effect is established in the case of the second layer system, that is to say that the layer system expands. As a result of the combination of the two layer systems in a multilayer coating, which layer systems, upon thermal loading, exhibit a change having opposite signs in the thickness and thus in the period length of the individual layer systems, the period length or the period thickness of the combined multilayer coating typically changes only slightly upon permanent thermal loading (i.e. upon a thermal loading that persists over a plurality of hours).

Within the meaning of this application, a thermal loading is understood as heating of the multilayer coating to a temperature of at least approximately 100° C., typically of 150° C. or more, in particular of 250° C. or more, wherein the temperature is maintained over a relatively long period of time (typically in the range of a plurality of hours), such that the above-described physical and/or chemical effects on the layers become apparent in a measurable change in the period thickness of the individual stacks.

The invention proposes that a (conventional) multilayer coating, which generally has only one layer system, the stacks of which contract, for example, upon a thermal loading and which therefore exhibits a period change having a negative sign, is supplemented by a second layer system, the stacks of which expand upon a thermal loading and thus produce a period change having the opposite sign. Moreover, the ratio of the number of (in each case two or more) stacks of the individual layer systems (i.e. the number of periods) relative to one another can also be optimized in order to obtain the best possible thermal and optical performance of the coating. What can be achieved as a result is that the centroid wavelength of the radiation reflected at the optical element or the coating, upon a thermal loading with a predefined (constant) temperature or with a predefined temperature profile, remains constant over a time duration that is typically as long as possible.

In the case of conventional multilayer coatings, the periodic layer design is modified by the addition of barrier layers in order to increase the thermal stability of the layer design. It goes without saying that the first and/or the second layer system can also have such barrier layers.

In one advantageous embodiment, the expansion of the stacks of the at least one second layer system compensates for the contraction of the stacks of the at least one first layer system of the multilayer coating. As a result of the contraction of the (at least one) second layer system being compensated for by the expansion of the (at least one) first layer system, the average period length or the thickness of the multilayer coating is maintained. In this way it can be ensured that the position of the interface of the multilayer coating with respect to the surroundings does not change appreciably in relation to the position of the surface of the substrate upon a permanent thermal loading.

The solution proposed here does not modify the period thickness of the multilayer coating by the addition of (further) barrier layers, but rather introduces new elements in the form of a periodic arrangement of stacks which compensate for the changes in the period length or the period thickness of the original coating. The design of the multilayer coating as proposed herein can therefore produce a higher reflectivity than in conventional multilayer coatings for the same thermal load, or alternatively a higher thermal stability for the same reflectivity. It goes without saying that the second layer system should compensate for changes in the period thickness of the first layer system over the greatest possible temperature range and the longest possible time duration.

It also goes without saying that two or more first and/or second layer systems can also be present in the multilayer coating, wherein in this case, too, it can be ensured that the combined changes in the period thicknesses of all the layer systems do not lead to a change in the “average” period thickness upon a thermal loading of the multilayer coating. The arrangement of the stacks of the layer systems in the multilayer coating is arbitrary, in principle. When distributing the stacks of the layer systems in the multilayer coating, care should be taken to ensure that the optical performance of the multilayer coating does not deteriorate drastically. Therefore, this should involve avoiding arrangement of all or virtually all stacks of the layer system having the greater absorption for the used radiation at the top side or adjacent to the interface of the multilayer coating with respect to the surroundings. An arrangement of all or virtually all stacks of the second, expanding layer system adjacent to the substrate has also proved to be disadvantageous for the optical properties of the multilayer coating.

In one embodiment, at least one layer of a stack of the second layer system contains boron. In principle, all materials that do not have serious adverse effects on the optical properties of the multilayer coating (e.g. excessively strong absorption) can be used as layers for the stacks of the second layer system. For producing an expansion upon the thermal loading of the layers of the second layer system, boron or boron compounds has/have proved to be advantageous. Boron has only three valence electrons, and so boron-metal compounds or boron-metal complexes are formed in the case of a boron-containing layer arranged, for example, adjacent to a layer containing a metallic material. The density of these compounds or complexes is typically lower than the density of the original constituents, which results in an expansion of the layers or of the stack.

In one development, the at least one layer is formed from B₄C. In the case of a layer composed of this material arranged adjacent to a layer composed of a metallic material, it was possible to detect an expansion upon thermal loading. It goes without saying, however, that other boron compounds or boron itself, particularly if these are arranged adjacent to a layer composed of a metallic material, can also lead to an expansion of the resulting layer stack.

In particular, the layer composed of B₄C can have a thickness of 2 nm or more, if appropriate of 3 nm or more. As described in the article “Interlayer growth . . . ” cited in the introduction, a B₄C layer having a thickness of 2 nm or more in combination with an adjacently arranged layer composed of Mo led to an expansion of the resulting stack, while a compaction of the layer stack was observed in the case of a thickness of less than 1.5 nm.

In a further embodiment, at least one layer of a stack of the second layer system contains a metal, in particular a transition metal, or consists of a metal, in particular a transition metal. As explained further above, in particular metal borides that form at the interface between the layers often have a lower density than the individual constituents, that is to say that the formation of metal borides is advantageous for the present use, i.e. for producing the expansion of the stacks of the second layer system.

In one development, the metal is selected from the group comprising: Mo and La. In the case of Mo, the expansion of a corresponding stack composed of Mo/B₄C was demonstrated in the article “Interlayer growth . . . ” cited above. Specific metals, in particular transition metals, such as e.g. La, also exhibit an expansion under suitable conditions (suitable layer thickness and suitable layer material for forming a chemical compound) upon thermal loading. Alongside the combination Mo/B₄C and/or La/B₄C, layer stacks composed of Mo/B and/or composed of La/B can also be used for the second layer system.

In a further embodiment, the layers of a stack of the second layer system contain both boron and a metal, wherein there is an excess of boron relative to the metal. The structure and thus the density of metal borides depends on the ratio between the metal portion and the boron portion. The enrichment of a metal or of a metal boride with boron generally leads to the formation of a compound having a lower density, such that it is advantageous if an excess of boron is present in the layers of the stacks of the second layer system. An excess of boron is understood to mean that there is a greater volume of boron than of metal or an overall greater thickness of boron layers than of metal layers in the stack.

In a further embodiment, at least one layer of a stack of the first layer system is formed from Mo or from Si. The first layer system can be, for example, a layer system which serves for reflecting EUV radiation (typically at 13.5 nm) and typically has layers composed of molybdenum which alternate with layers composed of silicon. It goes without saying that the first layer system can alternatively also have alternating layers composed of other layer materials, wherein typically materials having a high real part of the refractive index alternate with materials having a lower real part of the refractive index, in order to obtain the greatest possible reflectivity for radiation at a predefined wavelength.

In one embodiment, at least one layer of a stack of the first layer system is formed from B₄C. In this example, B₄C serves as a barrier layer between the layers composed of Si and Mo, that is to say in order to prevent to the greatest possible extent a diffusion of the two layer materials upon a thermal loading. A stack of the first layer system can in this case be constructed in particular as follows: Si/B₄C/Mo/B₄C, wherein the stack overall experiences a compaction upon a thermal loading, even though compounds (SiₓB_{y}) whose period thickness increases when subjected to thermal stress can form at the interface between Si and B₄C, as is described for example in the article “Thermally induced interface chemistry in Mo/B₄C/Si/B₄C multilayered films” by S. L. Nyabero et al., J. Appl. Phys. 112, 054317 (2012). It goes without saying that, instead of B₄C, other materials can also be used as barrier layers for the first layer system.

In a further embodiment, the ratio of the number of stacks of the first layer system to the number of stacks of the second layer system is 4:2. Such a ratio of the number of stacks of the respective layer systems has proved to be advantageous, in particular, if the first layer system has stacks consisting of Si/B₄C/Mo/B₄C and the second layer system has stacks consisting of Mo/B₄C, since, with this ratio, the expansion of the stacks of the second layer system precisely compensates for the contraction of the stacks of the first layer system of the multilayer coating upon a thermal loading as a result of heating to temperatures of e.g. approximately 250° C. It goes without saying that, depending on the type of materials and/or on the respective thermal loading to be compensated for, and/or the operating temperature of the optical element, other ratios between the number of stacks can also be set, wherein, of course, care should be taken to ensure that the optical properties of the coating do not deteriorate as a result of such a selection.

In a further embodiment, the multilayer coating is designed for reflecting EUV radiation. As was explained further above, such a multilayer coating typically has alternating layers composed of materials having high and low refractive indices. For a maximum wavelength of 13.5 nm, the layers having a higher real part of the refractive index are typically silicon layers, and the layers having a lower refractive index are layers composed of molybdenum. Other material combinations such as e.g. molybdenum and beryllium, ruthenium and beryllium or lanthanum and B₄C are likewise possible depending on the desired maximum wavelength.

A further aspect of the invention relates to an optical arrangement, in particular a lithography apparatus, comprising: at least one optical element as described above. The optical arrangement can be, for example, an EUV lithography apparatus for exposing a wafer, or some other optical arrangement which uses (EUV) radiation, for example a system for measuring masks used in EUV lithography. Optical arrangements which are operated at other wavelengths, e.g. in the VIS or UV wavelength range, can also be provided with one or a plurality of optical elements embodied as described above. What can be achieved with a multilayer coating embodied as described above is that the optical element having a particularly high reflectivity at a predefined wavelength or a particularly low reflectivity in the case of a multilayer coating in the form of an antireflection coating does not change, or only slightly changes, its optical properties even upon a permanent thermal loading e.g. as a result of heating to temperatures of approximately 100° C. or more.

In one embodiment, a centroid wavelength of the EUV radiation reflected at the optical element is or remains constant upon a thermal loading of the optical element by irradiation with EUV radiation. This can be achieved by virtue of the fact that the contraction of the period thickness of the first layer system is precisely compensated for by a corresponding expansion of the period thickness of the second layer system, such that the period thickness of the multilayer coating remains constant (on average). In this case, the thermal loading of the optical element corresponds to the operating temperature of the optical element in the optical arrangement, which is generated for example by the heating by EUV radiation—and, if appropriate, by additional temperature regulating devices, in particular heating devices.

In this case, before the introduction of the optical element into the optical arrangement or, if appropriate, before the commencement of the operation of the optical arrangement, e.g. exposure operation in the case of a lithography apparatus, if appropriate via heat treatment or with a thermal treatment, e.g. through brief heating and maintenance of a temperature of e.g. 250° C. over a plurality of minutes, the multilayer coating can be put into a state in which the period thickness and thus the centroid wavelength, i.e. the wavelength of maximum reflectivity, does not change upon a thermal loading, i.e. upon heating of the optical element or of the multilayer coating to operating temperature, over a very long period of time.

Further features and advantages of the invention are evident from the following description of exemplary embodiments of the invention, with reference to the figures of the drawing, and from the claims. The individual features can each be realized individually by themselves or as a plurality in any desired combination in a variant of the invention.

### BRIEF DESCRIPTION OF THE DRAWINGS

Exemplary embodiments are illustrated in the schematic drawing and are explained in the following description. In the figures:

FIG. 1 shows a schematic illustration of an EUV lithography apparatus,

FIGS. 2A and 2B show schematic illustrations of an optical element for the EUV lithography apparatus of FIG. 1 with a multilayer coating,

FIG. 3 shows an illustration of the period thickness or the change in the period thickness of a first and second layer system of the multilayer coating of FIG. 2b as a function of the duration of the thermal loading, and

FIG. 4 shows an illustration of the reflectivity of an optical element comprising the multilayer coating of FIG. 2B upon thermal loading for different periods of time.

### DETAILED DESCRIPTION

In the following description of the drawings, identical reference signs are used for identical or functionally identical component parts.

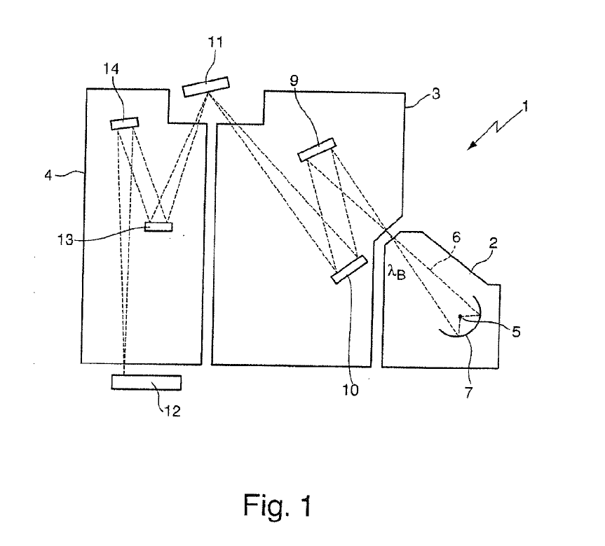

FIG. 1 schematically shows an optical system for EUV lithography in the form of a projection exposure apparatus 1 (EUV lithography apparatus). The projection exposure apparatus 1 comprises a beam generating system 2, an illumination system 3 and a projection system 4, which are accommodated in separate vacuum housings and are arranged successively in a beam path 6 proceeding from an EUV light source 5 of the beam generating system 2. By way of example, a plasma source or a synchrotron can serve as the EUV light source 5. The radiation emerging from the light source 5 in the wavelength range of between approximately 5 nm and approximately 20 nm is firstly focused in a collector mirror 7 and the desired operating wavelength λ_{B}, which is approximately 13.5 nm in the present example, is filtered out by a monochromator (not shown).

The radiation that has been treated with regard to wavelength and spatial distribution in the beam generating system 2 is introduced into the illumination system 3, which has a first and second reflective optical element 9, 10 in the present example. The two reflective optical elements 9, 10 direct the radiation onto a photomask 11 as a further reflective optical element, which has a structure that is imaged onto a wafer 12 on a reduced scale by the projection system 4. For this purpose, a third and fourth reflective optical element 13, 14 are provided in the projection system 4. It should be pointed out that both the illumination system 3 and the projection system 4 can have in each case only one or else three, four, five or more reflective optical elements.

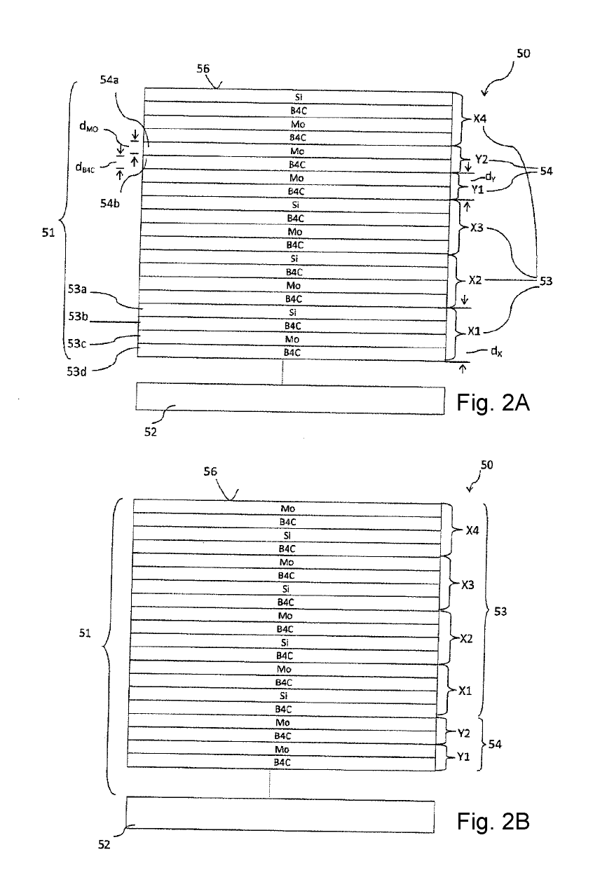

The structure of two optical elements 50 such as can be realized on one or a plurality of the optical elements 7, 9, 10, 11, 13, 14 of the projection exposure apparatus 1 from FIG. 1 is illustrated by way of example below with reference to FIGS. 2A, 2B. The optical elements 50 each comprise a substrate 52 consisting of a substrate material having a low coefficient of thermal expansion, e.g. of Zerodur®, ULE® or Clearceram®.

In the case of the reflective optical elements 50 illustrated in FIGS. 2A, 2B, a multilayer coating 51 is in each case applied to the substrate 52. The multilayer coating 51 of the optical elements 50 illustrated in FIGS. 2A, 2B comprises a first layer system 53 and a second layer system 54. The first layer system 53 consists of an arrangement of four stacks X1 to X4, the construction of which is identical in each case: each of the four stacks X1 to X4 consists of four layers 53a-d in the sequence Si/B₄C/Mo/B₄C. In this case, the first layer system 53 corresponds to a conventional layer system for reflecting EUV radiation, in which layer system barrier layers in the form of two layers 53b, 53d composed of B₄C are provided in order to increase the thermal stability. Upon a thermal loading that lasts for a relatively long period of time, the thickness dₓ of the stacks X1 to X4 decreases relative to the thickness produced upon application (here: d_{X}=6.9 nm, where d_{MO}=1.9 nm; d_{B4C}=1 nm; d_{Si}=3 nm), that is to say that the stacks Xl to X4 contract. The contraction of the stacks Xl to X4 can substantially be attributed to the formation of chemical compounds between the layer materials Si, Mo, B₄C at the interfaces between the layers 53a-d which have a higher density than the constituents of which they are composed.

The second layer system 54 consists of an arrangement of two stacks Y1, Y2 each having an identical layer construction: each stack Y1, Y2 consists of two layers 54a, 54b in the sequence Mo/B₄C. The B₄C layer 54b has a thickness d_{B4C} of 2 nm or more, preferably of 3 nm or more (in the present case d_{B4C}=4.2 nm), while the Mo layer 53a in the example shown has a thickness d_{MO} of approximately 3 nm and was applied by sputtering, for example. In the example described here, the stacks X1 to X4 of the first layer system 53 and the stacks Y1, Y2 of the second layer system 54 overall form a periodic arrangement, that is to say that the stack arrangement X4, Y2, Y1, X3, X2, X1 shown in FIG. 2A is repeated a plurality of times in the multilayer coating 51, to be precise exactly eight times in the present example. However, such a periodic arrangement of the stacks X1 to X4, Y1, Y2 in the multilayer coating 51 is not absolutely necessary.

The thickness d_{Y}=7.2 nm of the stacks Y1, Y2 of the second layer system 54, these thickness being produced during application, increases upon a thermal loading, that is to say that the stacks Y1, Y2 expand upon a thermal loading. For details with regard to a suitable design of the stacks Y1, Y2 of the second layer system 54 for producing an expansion, reference is made to the article “Interlayer growth . . . ” cited in the introduction, said article being incorporated by reference in the content of this application.

FIG. 2B shows an optical element 50 which differs from the optical element 50 shown in FIG. 2A merely in the arrangement of the stacks Y1, Y2 of the second layer system 54 in the multilayer coating 51 and in the sequence (Mo/B₄C/Si/B₄C) of the layers 53a-d in the stacks Xl to X4 of the first layer system 53. The arrangement of the stacks Y1, Y2 of the second layer system 54 and of the stacks X1 to X4 of the first layer system 53 in the multilayer coating 51 is arbitrary, in principle, provided that the optical properties of the multilayer coating are not influenced in a disadvantageous manner.

In particular, this should involve avoiding arrangement of all sixteen stacks Y1, Y2 of the second layer system 54 adjacent to an optical surface 56 which is shown in FIGS. 2A, 2B and which forms the interface with respect to the vacuum surroundings, in order that the reflectivity of the multilayer coating 51 is not reduced to an excessively great extent, since the stacks Y1, Y2 of the second layer system 54 have a higher absorption than the stacks X1 to X4 of the first layer system 53 for the EUV radiation. In order to avoid a change in the spectral reflectivity behavior of the multilayer coating 51, the sixteen stacks Y1, Y2 of the second layer system 54 should not be arranged adjacent to the substrate 52 either. It has proved to be advantageous if the (8×2=16) stacks Y1, Y2 of the second layer system 54 are arranged in a manner distributed over the multilayer coating 51, as is the case for example in the periodic arrangement in accordance with FIGS. 2A, 2B. However, it is also possible for the stacks Y1, Y2 of the second layer system 54 to be distributed over the multilayer coating in a non-periodic arrangement. By way of example, the stack arrangement X4, Y2, Y1, X3, X2, X1 shown in FIG. 2A can be combined with the stack arrangement X4, X3, X2, X1, Y2, Y1 shown in FIG. 2B in one and the same multilayer coating 51.

In order to protect a respective optical element 50 from contaminating substances from the vacuum surroundings, in the examples shown in FIGS. 2A, 2B, a protective layer system (not illustrated) is applied to the multilayer system 51, which protective layer system can be formed from one or from a plurality of layers and is unimportant for the present considerations, and so it will not be described in any greater detail here.

In the case of the optical elements shown in FIGS. 2A, 2B, the ratio of the number of stacks X1 to X4 of the first layer system 53 to the number of stacks Y1, Y2 of the second layer system 54 is chosen such that the contraction of the totality of the stacks X1 to X4 of the first layer system 53 upon a thermal loading is precisely compensated for by the expansion of the totality of the stacks Y1, Y2 of the second layer system 54, such that the average period thickness of the multilayer coating 51 and thus the distance between the interface 56 with respect to the vacuum and the top side of the substrate 52 of the optical element 50 are kept constant.

It goes without saying that, instead of B₄C layers 54b, the second layer system 54 can also comprise layers composed of other materials, for example composed of boron, and that other, in particular metallic, materials, specifically transition metals such as La, can also be used instead of molybdenum layers 54a. In the case of the combination of layers composed of boron and a metal, it has proved to be advantageous if a respective stack Y1, Y2 of the second layer system 54 has an excess of boron, that is to say if the boron volume in the respective stack Y1, Y2 (significantly) exceeds the volume of the metallic material.

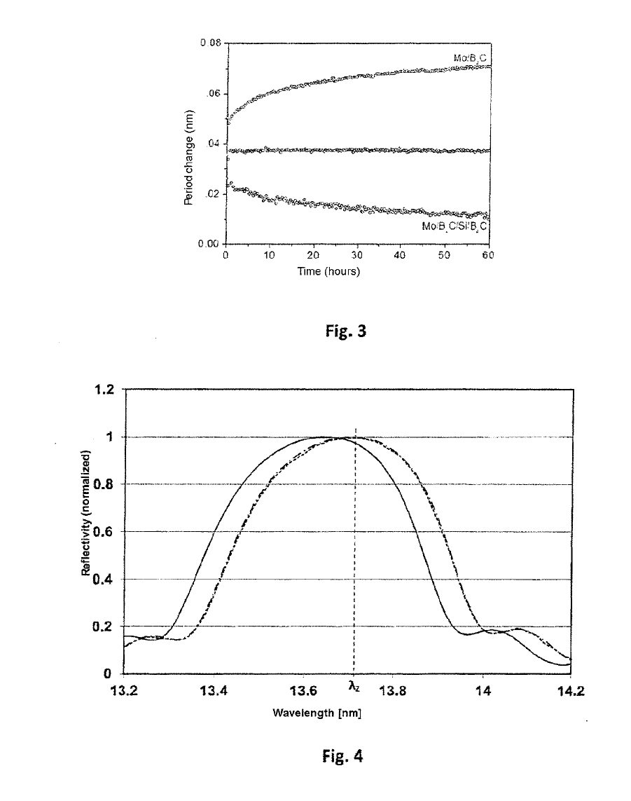

FIG. 3 shows the change in the period thickness of the totality of the stacks X1 to X4 of the first layer system 53 from FIG. 2B as a function of the time duration of the thermal loading, which, in the case of the illustration shown in FIG. 3, was produced by (permanent) heating to a temperature of 250° C. As can be gathered from the curves shown for Mo/B₄C and for Mo/B₄C/Si/B₄C, the contributions of the increase and the decrease in the period thickness of the two layer systems 53, 54 precisely cancel one another out, such that the change in the average period thickness of the multilayer coating 51 remains constant over time (cf. the middle curve). As can likewise be discerned in FIG. 3, the change in the period thickness relative to the applied thickness is not zero (which is attributable here to effects that will not be described in greater detail here), but the change in the period thickness arises directly at the beginning of the thermal treatment, such that a constant value is established after a short time (typically a few minutes).

The thermal behavior of the period thickness of the multilayer coating 51 as illustrated in FIG. 3 also affects the wavelength-dependent (normalized) reflectivity R of the optical element 50, to put it more precisely of the multilayer coating 51, which is shown in FIG. 4 at three different points in time of the thermal treatment: a first reflectivity curve (solid line) shows the reflectivity R of the multilayer coating 51 after coating, i.e. before the beginning of the thermal treatment, a second reflectivity curve (dash-dotted line) shows the reflectivity R after 10 minutes of the thermal treatment at 250° C., and a third reflectivity curve (dashed line) shows the reflectivity R after 60 hours of a thermal treatment at 250° C.

As is evident from the comparison of the second and third reflectivity curves from FIG. 4, the wavelength-dependent reflectivity R and thus also the centroid wavelength λ_{Z} (which ideally corresponds to the operating wavelength λ_{B}) no longer changes after a short thermal treatment of approximately 10 minutes, that is to say that the centroid wavelength λ_{Z} of the multilayer coating remains constant after this period of time. The shift in the reflectivity curve in the case of the (short) thermal treatment of 10 minutes can be taken into account in the design of the multilayer coating 51, that is to say that the shift can be taken into account with a margin when defining the thicknesses of the layers 53a-d, 54a,b of the multilayer coating 51. In this case, before the operation of the optical element 50 in the EUV lithography apparatus 1, a short thermal treatment e.g. of 10 minutes can be carried out in order to put the multilayer coating 51 into a state in which the centroid wavelength λ_{Z} no longer changes and corresponds to the desired wavelength.

The design of the multilayer coating, that is to say in particular the layer thicknesses but also the layer materials, can be adapted to the expected thermal loading or the operating temperature of the optical element. Since the thermal loading or the operating temperature of the optical elements 7, 9, 10, 11, 13, 14 of the EUV lithography apparatus 1 is typically different, a dedicated layer design of the multilayer coating 51 that is adapted to the expected operating temperature can be created in particular for each optical element 7, 9, 10, 11, 13, 14.

As a consequence of the period length that is constant over time, the angle-dependent reflected wavelength, intensity and wavefront of the radiation reflected by the multilayer coating 51 upon thermal loading typically do not change, that is to say that the optical performance of the multilayer coating 51 is maintained and the lifetime of the multilayer coating or of the associated optical element 50 is increased. The compensation proposed here is not restricted to the materials described above, rather, in principle a multiplicity of materials can be used which in total bring about a compensation of the expansion and contraction of the thicknesses of the stacks of the respective layer systems, provided that their use does not drastically reduce the optical properties of the multilayer coating. This is the case for example for materials which have an excessively high absorption coefficient for the radiation used.

A (virtually) complete compensation of the expansion and the compaction of the thicknesses of the stacks of the respective layer systems cannot be achieved in all cases. Even in this case, generally it is possible, in the manner described above, to obtain a multilayer coating 51 whose optical performance during operation with elevated temperatures decreases to a lesser extent than is the case for a multilayer coating consisting only of one layer system.

What is claimed is:

1. Optical element, comprising:
a substrate, and
a multilayer coating applied to the substrate, comprising:
at least one first layer system consisting of an arrangement of identically constructed stacks, each having at least two layers, and
at least one second layer system consisting of an arrangement of identically constructed stacks, each having at least two layers (54a, 54b),
wherein, upon a thermal loading of the multilayer coating (51), the first layer system is configured to experience an irreversible contraction of the thicknesses of the stacks and the second layer system is configured to experience an irreversible expansion of the thicknesses of the stacks.

2. The optical element according to claim 1, wherein the expansion of the stacks of the at least one second layer system compensates for the contraction of the stacks of the at least one first layer system of the multilayer coating.

3. The optical element according to claim 1, wherein at least one layer of a stack of the second layer system contains boron.

4. The optical element according to claim 3, wherein the layer of the stack of the second layer system is formed from B₄C.

5. The optical element according to claim 4, wherein the layer composed of B₄C has a thickness of at least 2 nm.

6. The optical element according to claim 1, wherein at least one layer of a stack of the second layer system contains a metal or consists of a metal.

7. The optical element according to claim 6, wherein the metal is selected from the group consisting of: Mo and La.

8. The optical element according to claim 1, wherein the layers of a stack of the second layer system contain both boron and a metal, wherein there is an excess of boron relative to the metal.

9. The optical element according to claim 1, wherein at least one layer of a stack of the first layer system is formed from Mo or from Si.

10. The optical element according to claim 1, wherein at least one layer of a stack of the first layer system is formed from B₄C.

11. The optical element according to claim 1, wherein the ratio of the number of stacks of the first layer system to the number of stacks of the second layer system is 4:2.

12. The optical element according to claim 1, wherein the multilayer coating is configured for reflecting extreme ultraviolet (EUV) radiation.

13. An optical arrangement, comprising: at least one optical element according to claim 1.

14. The optical arrangement according to claim 13, configured as a lithography apparatus.

15. The optical arrangement according to claim 13, wherein, upon a thermal loading of the optical element by irradiation with EUV radiation, a centroid wavelength of the EUV radiation reflected at the optical element is constant.
